(19) United States
(12) Patent Application Publication
(10) Pub. No.: US 2006/0220692 A1
(43) Pub. Date: Oct. 5, 2006

(54) Sample-hold circuit and semiconductor device

(75) Inventor: Hiroyuki Hirashima, Soraku-gun (JP)

Correspondence Address: HARNESS, DICKEY & PIERCE, P.L.C., P.O. BOX 8910, RESTON, VA, 20195, US

(73) Assignee: Sharp Kabushiki Kaisha

(21) Appl. No.: 11/390,344

(22) Filed: Mar. 28, 2006

(30) Foreign Application Priority Data
Mar. 29, 2005 (JP) P2005-094708

(51) Int. Cl. G11C 27/02; H03K 5/00

(52) U.S. Cl. 327/91

(57) ABSTRACT

A first sampling capacitor 3 is connected between an output terminal of a first analog switch 1 and the ground, and an input terminal of a second analog switch 2 is connected to a node between the first analog switch 1 and the first sampling capacitor 3. A second sampling capacitor 4 is connected between an output terminal of the first analog switch 1 and the ground. A control part turning on the first and second analog switches 1 and 2 in a state in which an input voltage is applied to the input terminal of the first analog switch 1, thereafter turns off the second analog switch 2, subsequently turns off the first analog switch 1 and subsequently turns on the second analog switch 2.

This nonprovisional application claims priority under 35 U.S.C. §119(a) on Patent Application No. 2005-094708 filed in Japan on Mar. 29, 2005, the entire contents of which are hereby incorporated by reference.

### BACKGROUND OF THE INVENTION

The present invention relates to a sample-hold circuit in which a capacitor and an analog switch are combined with each other and relates, in particular, to a sample-hold circuit suitable for use in an LCD (Liquid Crystal Display) drive circuit or the like that outputs an LCD drive voltage to an LCD panel. The present invention also relates to a semiconductor device that has the sample-hold circuit.

In recent years, attention has been paid to a TFT (Thin Film Transistor) LCD panel characterized by a low voltage, a lightweight and a thin configuration as a display device that takes the place of CRT (Cathode Ray Tube) in a computer and a television set.

FIG. 9 is a block diagram showing a general LCD drive circuit (LCD driver).

Reference is made below to a case where an LCD driver of 300 outputs is employed, data of one pixel is constructed of 6 [Bit]×3 (corresponding to red, green and blue (abbreviated as RG-B hereinbelow))=18 [Bit] and the input is taken in by 6 [Bit]×3 (RGB) at a time.

An LCD driver 107 is constructed of a first line memory 101 that samples data of each pixel, a second line memory 102 that holds data of one display line, a DA converter (digital-to-analog converter) 103, an LCD drive output amplifier circuit 104, a control section (control circuit) 105 and a reference power supply section 106.

The data of pixels are successively inputted to the LCD driver 107 every pixel. In concrete, the control section 105 controls the first line memory 101 and successively stores the inputted data into the first line memory 101. Since the input is taken in by 6 [Bit]×3 (R-G-B) at a time, data intake is to be performed 100 times in order to take in the data of 300 outputs.

The data of one line is stored into the first line memory 101, and thereafter, the data of the first line memory 101 is transferred to the second line memory 102 by a signal from the control section 105. The DA converter 103 converts the digital data stored in the second line memory 102 into analog data. The conversion is performed by selecting an appropriate voltage out of 64-level voltages produced by the reference power supply section 106 on the basis of the input digital data. Subsequently, the selected voltage is subjected to impedance conversion in the LCD drive output amplifier 104 and outputted from the LCD driver 107. The output is given to the source line (X-direction) of the LCD panel, and a display on the LCD panel is achieved.

In recent years, the DA converter size tends to increase in accordance with a finer resolution. For example, a fourfold size results when the 64-level DA converter is modified to 256-level gray scale, and a sixteenfold size results in the case of 1024-level gray scale. Since a DA converter is provided for each output in the LCD driver of the construction shown in FIG. 9, an increase in the DA converter size leads to an increase in the chip area.

As a method capable of avoiding the increase in the chip area, there is a method of sequentially carrying out DA conversion (digital-to-analog conversion) and storing the result into a sample-hold circuit.

FIG. 10 is a diagram showing one example of the sample-hold circuit part, and FIG. 12 is a block diagram of an LCD driver 207 that has the sample-hold circuit part shown in FIG. 10.

As shown in FIG. 10, the sample-hold circuit part has capacitors 111 and 113, and analog switches 110 and 112. In FIG. 12, input image data of 6 [Bit]×3 (RGB) is inputted to the LCD driver 207 at a time. The DA converter 120 converts the input image data into analog data expressed by 64-level voltage data. The DA converter 120 has three conversion circuits and is able to process data of the colors (R-G-B) at a time.

When the input image data is taken in, the DA converter 120 operates. In detail, the DA converter 120 converts the input image data into analog data and outputs the converted analog data to an analog S/H (Sample-Hold) circuit part 121.

The conversion timing is controlled by the control section 205. The output from the DA converter 120 to the analog S/H circuit part 121 can be transferred on one signal line with regard to each of the colors (R-G-B) Therefore, the circuit scale subsequent to the DA converter 120 is not increased even when the gray scale levels of the DA converter 120 are increased. Since the DA converter 120 is a general DA converter, no description is provided for the circuit construction.

The sample-hold circuit part shown in FIG. 10 takes charge of one output of the analog S/H circuit part 121 shown in FIG. 12.

A general sample-hold circuit part can be constructed of an analog switch and a capacitor. However, when a sample-hold circuit part is employed in an LCD driver, it is necessary to sample data of the next stage while an LCD panel is driven by the held voltage. In this case, a sample-hold circuit part is constructed of analog switches 110 and 112, and capacitors 111 and 113 as shown in FIG. 10.

The analog voltage from the DA converter 120 is held in the capacitor 111 by a signal CK, the voltage held in the capacitor 111 is transferred to the capacitor 113 by a signal LP, and the capacitor 113 holds the voltage. While the voltage held in the capacitor 113 drives the LCD panel through the LCD drive output amplifier 104, the sample-hold circuit part constructed of the analog switch 110 and the capacitor 111 samples the data of the next stage.

Although the sample-hold circuit part of FIG. 10 has the analog switches 110 and 112 connected in series, there is also a construction of FIG. 11 in which a sample-hold circuit part constructed of an analog switch 210 and a capacitor 211 is connected in parallel with a sample-hold circuit part constructed of an analog switch 212 and a capacitor 213. In the construction of FIG. 11, while the LCD panel is driven by the voltage held in the capacitor 211, the voltage of the next stage outputted from the DA converter to the capacitor 213 is sampled and held, and conversely, while the LCD panel is driven by the voltage held in the capacitor 213, the voltage of the next stage outputted from the DA converter to the capacitor 211 is sampled and held in the capacitor 211.

In FIG. 10, the input voltage is an analog data converted by the DA converter 120. The analog switch 110 is controlled to be turned on and off by the signal CK controlled by the control section 205. Then, the capacitor 111 is charged with the analog data during the period in which the analog switch 110 is in the on state. By controlling the timing of the signal CK, the analog data outputted in time series from the DA converter 120 can be successively sampled every output.

The voltage taken in the capacitor portion 111 is referred to as voltage 1. The analog switch 112 is controlled to be turned on and off by a signal LP controlled by the control section 205. The sampling voltage 1 is transferred to the capacitor 113 during the period in which the analog switch 112 is in the on state. The voltage transferred to the capacitor 113 is referred to as voltage 2.

The analog S/H circuit part 121 in FIG. 12 includes a number of circuits shown in FIG. 10, the number being equal to the number of outputs. For example, in the case of 300 outputs of the three systems of R-G-B, data intake is ended by sampling 100 times. When the sampling is performed 100 times, the voltage 1 is established with regard to all outputs.

Subsequently, the voltage 1 is transferred by a signal from the control section 205 and becomes the voltage 2, and the voltage 2 is subjected to impedance conversion by the LCD drive output amplifier 104 and outputted. The output is given to the source line (X-direction) of the LCD panel, and the display on the LCD panel is achieved.

In the LCD driver 207 of the structure shown in FIG. 12 that employs the sample-hold circuit parts in each of which the capacitor and the analog switch are combined with each other, even if the number of gray scale levels is increased in accordance with a finer resolution, only the scale of the DA converter 120 that converts the input data is enlarged, and the scale of the output circuit portion that occupies the greater part of the area of the LCD driver 207 is not enlarged. Therefore, the chip area is not increased in accordance with the finer resolution.

If the sample-hold circuit in which the capacitor and the analog switch are combined with each other is employed as described above, the area occupied by the output circuit portion can largely be reduced, and therefore, a high-definition LCD drive circuit excellent in quality can be manufactured. However, there is a problem that accurate sampling cannot be performed since a parasitic capacitance owned by the analog switch is actually varied by the turning on and off of switching. Accordingly, there is a problem that the sample-hold circuits of the constructions shown in FIGS. 10 and 11 cannot be used for a high-definition LCD drive circuit.

FIG. 14 is a timing chart for explaining a conventional sample-hold circuit part. As shown in FIG. 14, a voltage error AV attributed to the parasitic capacitance of the analog switch occurs in the sampling voltage that is the output voltage. This therefore leads to a problem that accurate sampling cannot be performed.

JP H07-86935 A discloses the problem caused by the parasitic capacitance of the analog switch in the sample-hold circuit shown in FIG. 13 and a reform measure of the problem. In detail, a problem that the input voltage and the sample hold voltage are changed by the parasitic capacitance of the analog switch is described, and a reform measure for avoiding the problem of the parasitic capacitance is disclosed.

FIGS. 15 and 16 are diagrams for explaining the reform measures.

As shown in FIGS. 15 and 16, the reform measures are to introduce a capacitor 305 that has a sufficiently large capacitance in comparison with the capacitance of the capacitor 301 used for sampling hold, connect the capacitor 305 of the large capacitance at the sampling time and disconnect the capacitor 305 at the holding time with analog switches 303 and 304 which are controlled by a signal SD. As described above, a variation in the voltage due to the influence of the parasitic capacitance is reduced by temporarily increasing the capacitance at the sampling time.

However, the method has a problem that the error cannot sufficiently be corrected. Moreover, the method has a problem that a time for charging the capacitor 305 with electric charge in the sampling operation (time for charging the capacitance) becomes long to prolong the sampling time although no influence is exerted on the circuit operation subsequent to the sample-hold circuit since the synthetic capacitance of the capacitors 301 and 305 is adjusted so as to become reduced after the sampling of the input voltage by switching over the analog switches 303 and 304.

### SUMMARY OF THE INVENTION

An object of the present invention is to provide a sample-hold circuit capable of correcting the voltage variation of the sample-hold circuit attributed to the variation in the parasitic capacitance of the analog switch caused by turning on and off the analog switch without increasing the capacitance of the capacitor of the sample-hold circuit

In order to achieve the above object, there is provided a sample-hold circuit comprising:

a first analog switch;

a first sampling capacitor connected between an output terminal of the first analog switch and a ground;

a second analog switch whose input terminal is connected to a node between the first analog switch and the first sampling capacitor;

a second sampling capacitor connected between an output terminal of the second analog switch and the ground; and

a control section for performing first control for turning on the first and second analog switches, thereafter performing second control for turning off the second analog switch in a state in which the first analog switch is on, subsequently performing third control for turning off the first analog switch in a state in which the second analog switch is off and subsequently performing fourth control for turning on the second analog switch in a state in which the first analog switch is off.

According to the present invention, the control section turns on the first and second analog switches by the first control, thereafter turns off the second analog switch by the second control, subsequently turns off the first analog switch by the third control and thereafter turns on the second analog switch by the fourth control. Therefore, a change in the sampling voltage that is the voltage at the node between the second analog switch and the second sampling capacitor and is changed by the parasitic capacitance (stray capacitance) of the second analog switch when the second analog switch is turned off by the second control and a change in the sampling voltage changed by the parasitic capacitance of the second analog switch when the second analog switch is turned on by the fourth control can cancel each other. Therefore, a sampling voltage error due to the parasitic capacitances of the first and second analog switches can be corrected. Therefore, accurate sampling can be performed, and display on the LCD panel, for example, can be achieved much more elaborately than in the conventional case.

Moreover, according to the sample-hold circuit of the present invention, the effect of the parasitic capacitance of analog switches can be canceled. Therefore, it is unnecessary to increase the capacitance of the capacitor so that the effect of the parasitic capacitance of the analog switches is reduced unlike the conventional practice. Therefore, the sampling capacitance of the capacitor can be made much smaller than in the conventional case. Therefore, the time for charging the sampling capacitance can be remarkably shortened, and the sampling time can be remarkably reduced.

In one embodiment, the control section performs the first, second, third and fourth controls during a period in which an input voltage applied to an input terminal of the first analog switch does not substantially change.

One embodiment further comprises a digital-to-analog converter that outputs an analog voltage based on external input digital data, wherein the input voltage is the analog voltage outputted from the digital-to-analog converter.

In one embodiment, the first sampling capacitor has a capacitance equal to a capacitance of the second sampling capacitor.

According to the embodiment, the capacitance of the first capacitor is equal to the capacitance of the second capacitor. Therefore, the change in the sampling voltage when the second analog switch is turned off and the change in the sampling voltage when the second analog switch is turned on can be brought close to each other, and this allows the amount of cancellation to be increased. Therefore, the sampling voltage error can further be reduced.

According to the embodiment, the parasitic capacitance of the first analog switch is equal to the parasitic capacitance of the second analog switch, and therefore, the sampling voltage error can further be reduced.

In one embodiment, the first sampling capacitor and the second sampling capacitor are built in an identical integrated circuit, and

the first sampling capacitor is roughly identical to the second sampling capacitor.

According to the embodiment, by making the layout of the components (electrode plate etc.) of the first sampling capacitor and the layout of the components of the second sampling capacitor roughly equal to each other, the capacitances of the first and second capacitors can be equalized, and the sampling voltage error can further be reduced.

In one embodiment, the first analog switch and the second analog switch are built in the integrated circuit that has the first sampling capacitor and the second sampling capacitor and wherein,

the first analog switch is constituted of a plurality of transistors, the second analog switch is constituted of a plurality of transistors, and

a layout of the plurality of transistors that constitute the first analog switch is equal to a layout of the plurality of transistors that constitute the second analog switch.

According to the embodiment, the parasitic capacitance of the first analog switch is equal to the parasitic capacitance of the second analog switch, and the capacitances of the first sampling capacitor and the second capacitor are equal to each other. Therefore, the sampling voltage error can further be reduced.

Moreover, according to the embodiment, the sampling voltage error due to the parasitic capacitances of the analog switches can be corrected. Therefore, it is unnecessary to increase the sampling capacitors in order to reduce the voltage error due to the parasitic capacitances of the analog switches, and the effects of reducing a chip area thereof and shortening the sampling time in the sample-hold circuit are also produced.

A semiconductor device of one embodiment comprises the sample-hold circuit.

Since the semiconductor device of the embodiment has the sample-hold circuit, the desired sampling voltage can accurately be taken out by the sample-hold circuit, and the sampling time in the sample-hold circuit can remarkably be shortened. Therefore, the quality of the semiconductor device can remarkably be improved.

According to the sample-hold circuit of the present invention, which has the control section, the two analog switches for correction and the two sampling capacitors and in which the timing of turning on and off the two analog switches is shifted by the control section, the error generated by the combination of the sampling capacitors and the analog switches can be corrected with high accuracy, and the desired sampling voltage can be obtained.

Moreover, according to one embodiment, the sampling capacitor is divided into two, one analog switch is inserted between the two sampling capacitors, and further the two analog switches and the two sampling capacitors have same sizes, respectively. Therefore, by adjusting the timing of turning on and off the analog switches, the error in the hold voltage due to the parasitic capacitance of the analog switches can be corrected. Therefore, it is only required to determine the capacitance value taking the sampling rate and the operation speed of the subsequent circuits into consideration, and it is unnecessary to set a large capacitance for reducing the error in the hold voltage due to the parasitic capacitance of the analog switches. Therefore, the chip area can be reduced, and the sampling time can be reduced.

### BRIEF DESCRIPTION OF THE DRAWINGS

The present invention will become more fully understood from the detailed description given hereinbelow and the accompanying drawings which are given by way of illustration only, and thus are not intended to limit the present invention, and wherein:

FIG. 1 is a circuit diagram of an LCD drive sample-hold circuit of one embodiment of the present invention;

FIG. 2 is a timing chart of the LCD drive sample-hold circuit of the embodiment;

FIG. 3 is a diagram showing one concrete example of a construction of part of the LCD drive sample-hold circuit of the embodiment;

FIG. 4 is a diagram showing a concrete construction of the second analog switch shown in FIG. 3;

FIG. 5 is a timing chart showing an operation of the construction shown in FIG. 3;

FIG. 6 is a block diagram of an LCD driver that has the sample-hold circuit of the embodiment;

FIG. 7 is a diagram showing a construction of an analog S/H circuit part owned by the LCD driver;

FIG. 8 is a timing chart when the sample-hold circuit of the embodiment is applied to the LCD driver;

FIG. 9 is a block diagram showing a general LCD drive circuit (LCD driver);

FIG. 10 is a diagram showing a circuit construction of a sample-hold circuit part;

FIG. 11 is a diagram showing a circuit construction of a sample-hold circuit part;

FIG. 12 is a block diagram of an LCD driver that has either of the sample-hold circuit parts shown in FIGS. 10 and 11;

FIG. 13 is a diagram showing a circuit construction of a conventional sample-hold circuit;

FIG. 14 is a timing chart of a conventional sample-hold circuit;

FIG. 15 is a diagram showing a circuit construction of a conventional sample-hold circuit;

FIG. 16 is a diagram showing a circuit construction of a conventional sample-hold circuit;

### DETAILED DESCRIPTION OF THE INVENTION

The present invention will be described in detail below by the embodiment shown in the drawings.

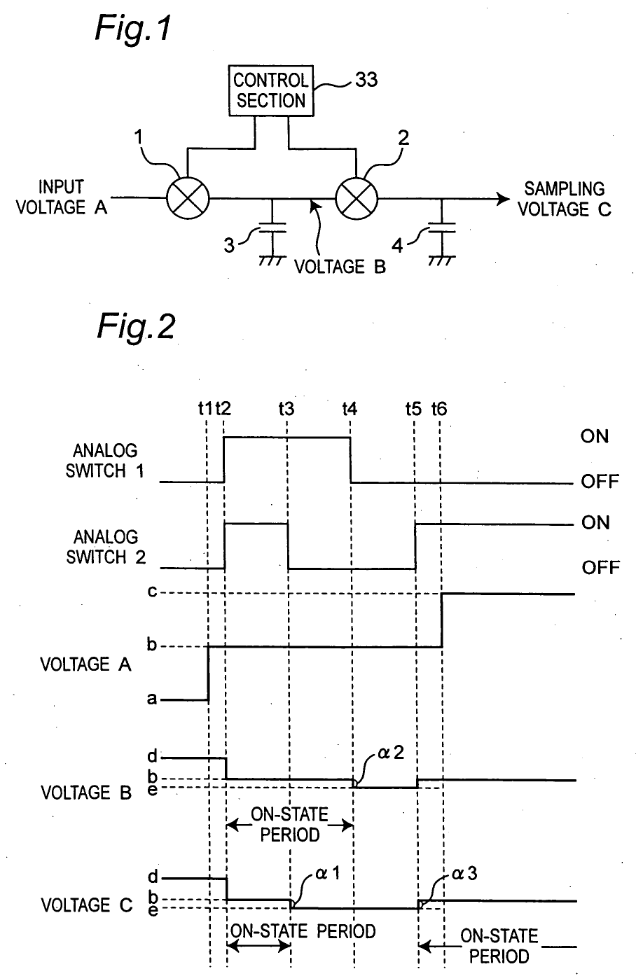

FIG. 1 is a circuit diagram of an LCD drive sample-hold circuit of one embodiment of the present invention. FIG. 2 is a timing chart of the LCD drive sample-hold circuit of the embodiment. In FIG. 2, a voltage A is an input voltage A shown in FIG. 1, a voltage B is a voltage B shown in FIG. 1, and a voltage C is a sampling voltage C shown in FIG. 1.

As shown in FIG. 1, the LCD drive sample-hold circuit includes a first analog switch 1, a second analog switch 2, a first sampling capacitor 3, a second sampling capacitor 4 and a control section 33. The first analog switch 1 and the second analog switch 2 are analog switches of same size and same structure. Moreover, the first sampling capacitor 3 and the second sampling capacitor 4 are capacitors of same size and same structure.

The input voltage A is applied to an input terminal of the first analog switch 1. The first sampling capacitor 3 is connected between an output terminal of the first analog switch 1 and the ground. One end of a wiring line is connected to a node between the first analog switch 1 and the first sampling capacitor 3, and the other end of the wiring line is connected to an input terminal of the second analog switch 2.

The second sampling capacitor 4 is connected between the output terminal of the second analog switch 2 and the ground. An electrical potential (node voltage) at the node between the second analog switch 2 and the second sampling capacitor 4 with respect to the ground is taken out as the sampling voltage C.

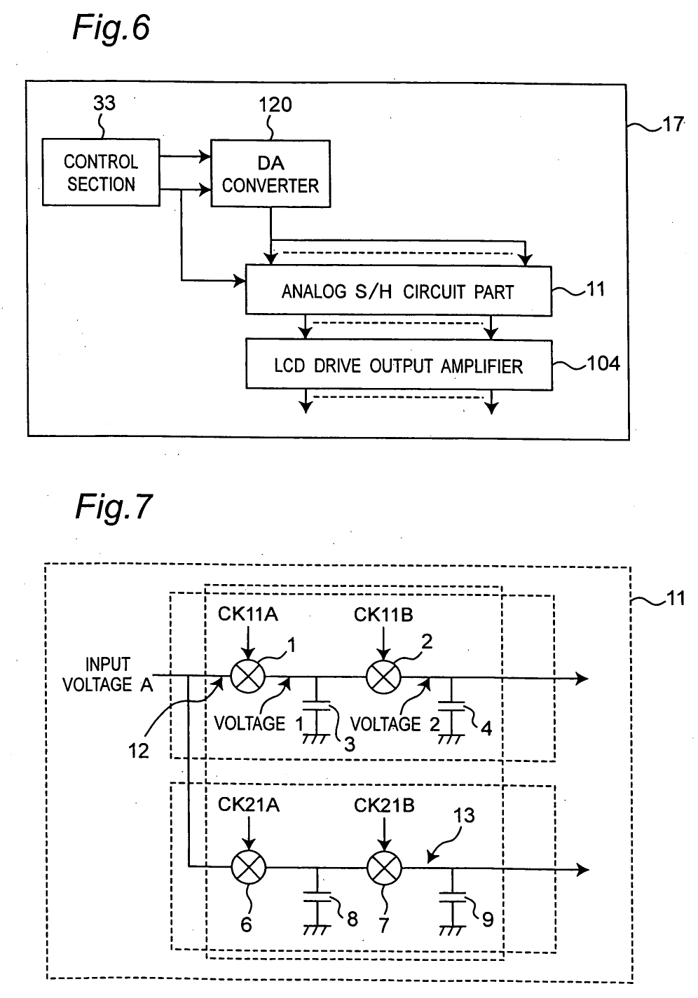

The input voltage A in FIG. 1 is an analog voltage produced by a DA converter (digital-to-analog converter) 120 of FIG. 6, for example, or the like. As shown in FIG. 2, the input voltage A changes in accordance with the timing at time t1 and time t6 (>t1), and the voltage does not change in the period of time t1 to time t6. In detail, the input voltage A changes in level from “a” to “b” at time t1 and changes from “b” to “c” at time t6.

A time indicated by t2 (>t1) in FIG. 2 is the sampling start timing. That is, in the LCD drive sample-hold circuit, the control section 33 performs first control at time t2. In concrete, the first analog switch 1 and the second analog switch 2 are simultaneously turned on by a control signal from the control section 33 at time t2. Although the first analog switch 1 and the second analog switch 2 are simultaneously turned on by the first control in the embodiment, the first analog switch 1 and the second analog switch 2 are not always required to be simultaneously turned on by the first control.

As shown in FIG. 2, while the first and second analog switches 1 and 2 are turned on, i.e., during the time from time t2 to time t3 (>t2), the first sampling capacitor 3 is supplied with the input voltage A at level b. Moreover, the second sampling capacitor 4 is similarly supplied with the input voltage B at level b.

Moreover, as shown in FIG. 2, second control is performed at time t3. That is, the second analog switch 2 is turned off at time t3 by the control signal of the control section 33. The parasitic capacitance of the second analog switch 2 changes due to the second analog switch 2 turned off at the timing of time t3, and this changes the sampling voltage C that is the node voltage between the second analog switch 2 and the second sampling capacitor 4 to a voltage at level e shifted by a voltage α1 from the voltage at level b of the input voltage.

The input voltage A at level b is applied to the input terminal at this point of time. Therefore, the voltage applied to the first sampling capacitor 3 is the input voltage A at level b, and the voltage B between the first analog switch 1 and the first sampling capacitor 3 is at level b.

Next, third control is performed at the timing t4 (>t3). That is, the first analog switch 1 is turned off by the control signal of the control section 33. Since the first analog switch 1 is turned off at the timing t4, the parasitic capacitance of the first analog switch 1 changes, and this changes the voltage B that is the node voltage between the first analog switch 1 and the first sampling capacitor 3 to a voltage shifted by a voltage α2 from the voltage at level b of the input voltage. In this case, since the voltage α1 and the voltage α2 have same voltage due to the circuit construction and sequence, the sampling voltage of the voltage B has level e.

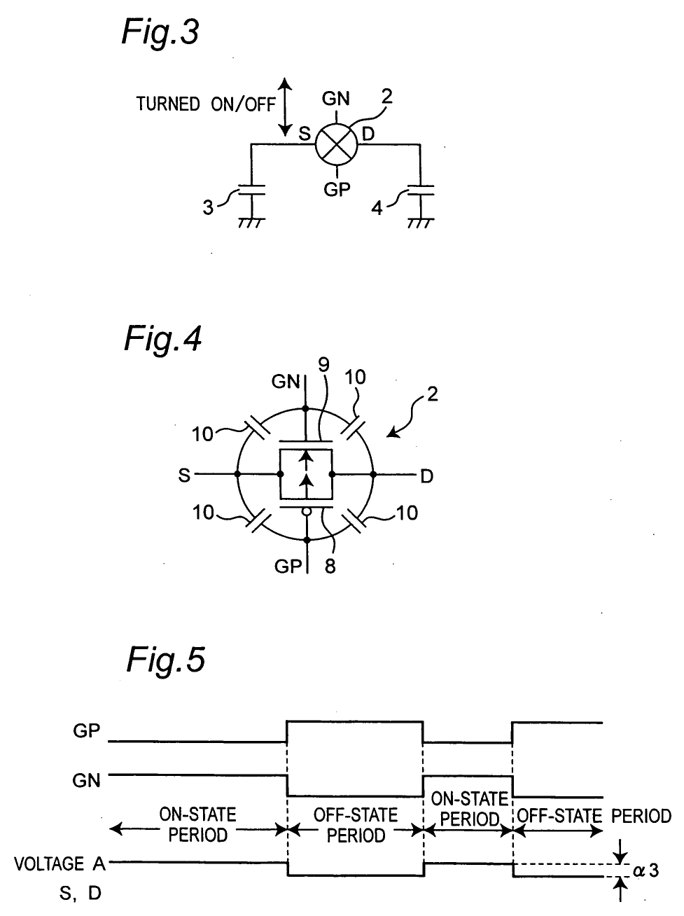

Next, fourth control is performed at the timing t5 (>t4). That is, the second analog switch 2 is turned on by the control signal of the control section 33. Since the second analog switch 2 is turned on at the timing of time t5, the parasitic capacitance of the second analog switch 2 changes, and this changes the voltage C that is the node voltage between the second analog switch 2 and the second sampling capacitor 4 to a voltage shifted by a voltage α3 from the voltage at level b. At this time, the voltages of α2 and α3 have same voltage. This is described with reference to FIG. 3.

FIG. 3 schematically illustrates the construction of the present invention. FIG. 4 is a diagram showing the concrete construction of the second analog switch 2 shown in FIG. 3.

In FIG. 3 are shown the analog switch 2, the first capacitor 3 and the second capacitor 4. The first capacitor 3 is the same capacitor as the second capacitor 4 and has same capacitance.

As shown in FIG. 4, the analog switch 2 is constructed of a Pch transistor (P-channel transistor) 8 and an Nch transistor (N-channel transistor) 9. In FIG. 4, a reference numeral 10 denotes the parasitic capacitance of the analog switch 2. In FIGS. 3 and 4, S indicates the source of the analog switch 2, and D indicates the drain of the analog switch 2. Moreover, in FIGS. 3 and 4, GP indicates a gate signal of the Pch transistor, and GN indicates a gate signal of the Nch transistor.

FIG. 5 is a timing chart showing the operation of the construction shown in FIG. 3. In FIG. 5, the last line indicates the voltage of the source S and drain D of the analog switch 2. Moreover, in FIG. 5, GP indicates the gate signal of the Pch transistor 8, and GN indicates the gate signal of the Nch transistor 9.

It is assumed that the first and second capacitors 3 and 4 shown in FIG. 3 are charged with electric charges by some means in a state in which the analog switch 2 is on and each of ends of the analog switch 2 is the voltage A. Next, the voltage relations of the gate to the source S and drain D of the analog switch 2 change when the analog switch 2 is turned off, and therefore, the parasitic capacitance of the analog switch 2 changes to cause a variation to the voltage A by the voltage α3.

Attention should be paid here to the fact that, since the voltage relations of the gate to the source S and drain D of the analog switch 2 is restored when the analog switch 2 is turned off and thereafter turned on again unless a leakage current is generated, the variation in the parasitic capacitance is also restored and the voltage of the capacitor is restored to the original voltage A. Therefore, due to the variation in the parasitic capacitance of the analog switch 2 at the time of switching between the on and off states performed in the structure shown in FIG. 3, there is a recurrence as shown in FIG. 5 although the charging voltage of the capacitor 4 changes.

If the state of FIG. 3 is applied to FIG. 1, the numeral 2 corresponds to the second analog switch, the numeral 3 corresponds to the first sampling capacitor, and the numeral 4 corresponds to the second sampling capacitor.

In the case of the circuit diagram of FIG. 1 and the sequence diagram of FIG. 2, the circuit of FIG. 1 is equivalent to the off state of the analog switch 2 of FIG. 3 in the stage in which the first analog switch 1 is in the off-state at time t4.

When the initial voltage of the capacitors 3 and 4 of FIG. 3 is equal to the input voltage A (level b) of FIG. 1, the voltages applied to the gate, the drain, the source and the backgate of the analog switch 2 of FIG. 3 are the same as those of the analog switch 2 at times t3 and tS and of the analog switch 1 at time t4, and therefore, an equation: α1=α2=α3 holds between the voltages indicated by α1 and α2 shown in FIGS. 1 and 2 and the voltage indicated by α3 in FIGS. 2 and 5.

Therefore, when the analog switch 2 of FIG. 1 is turned on again at the timing of t5 of FIG. 2 in the sample-hold circuit of the embodiment, the voltage B and the voltage C can be expected to have level b of the initial voltage as in the model of FIG. 3.

Actually, the voltage across both ends of the second analog switch 2 of FIG. 1 at time t4 in the timing chart of FIG. 2 differs by the voltage α1 from the voltage across both ends of the analog switch 2 of FIG. 3 when the analog switch 2 of FIG. 3 is off, and therefore, the voltages α1, α2 and α3 are strictly not same but slightly varied by an error generated. However, the error generated in the sample-hold circuit of the embodiment is much less than the error generated in the conventional sample-hold circuit, and display on the LCD panel can more accurately be achieved than in the conventional case.

FIG. 6 is a block diagram of an LCD driver 17 that has the sample-hold circuit of the embodiment. The sample-hold circuit includes an analog S/H circuit part 11, a DA converter 120 and the control section 33.

Input image data of 6 [Bit]×3 (RGB) (=18 [Bit]) is inputted to the LCD driver 17 at a time. The DA converter 120 converts LCD display digital data into analog data and outputs the analog data to the analog S/H circuit part 11. Moreover, the analog S/H circuit part 11 samples and holds the analog data from the DA converter 120 and outputs an LCD drive voltage.

In detail, the DA converter 120 converts the input image data into analog data expressed by voltage data of 64-level gray scale. The DA converter 120 has. converters of three circuits and is able to process data of the colors (RGB) at a time.

The DA converter 120 sequentially transfers the analog value obtained after the DA conversion to the analog S/H circuit part 11. That is, when the input image data is taken in, the DA converter 120 operates to convert the input image data into the analog data and outputs the converted analog data to the analog S/H circuit part 11.

The conversion timing is controlled by the control section 13. The output from the DA converter 120 to the analog S/H circuit part 11 can be transferred on one signal line with respect to each of the colors (RGB).

FIG. 7 is a diagram showing the construction of the analog S/H circuit part 11 in FIG. 6. It is noted that the input voltage A in FIG. 7 is outputted from the DA converter 120 in FIG. 6.

The analog S/H circuit part 11 shown in FIG. 7 has a structure in which two units of the sample-hold circuit part shown in FIG. 1 are connected in parallel. In detail, the analog S/H circuit part 11 has a first sample-hold circuit part 12 and a second sample-hold circuit part 13. The first and second analog switches 1 and 2 of the first sample-hold circuit 12 and the first and second analog switches 6 and 7 of the second sample-hold circuit part 13 are all same analog switches. Moreover, the sampling capacitors 3 and 4 of the first sample-hold circuit part 12 and the sampling capacitors 8 and 9 of the second sample-hold circuit part 13 are all same capacitors.

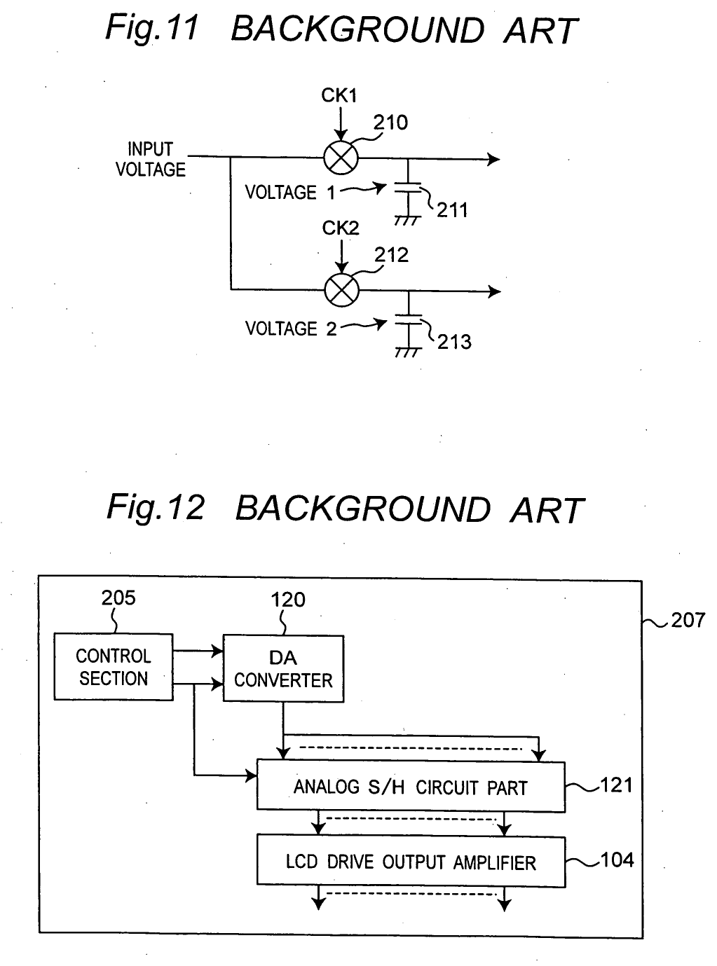

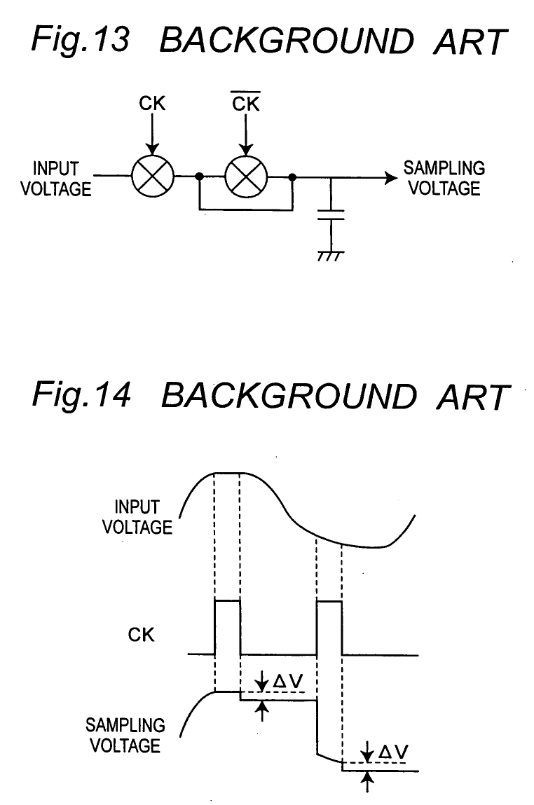

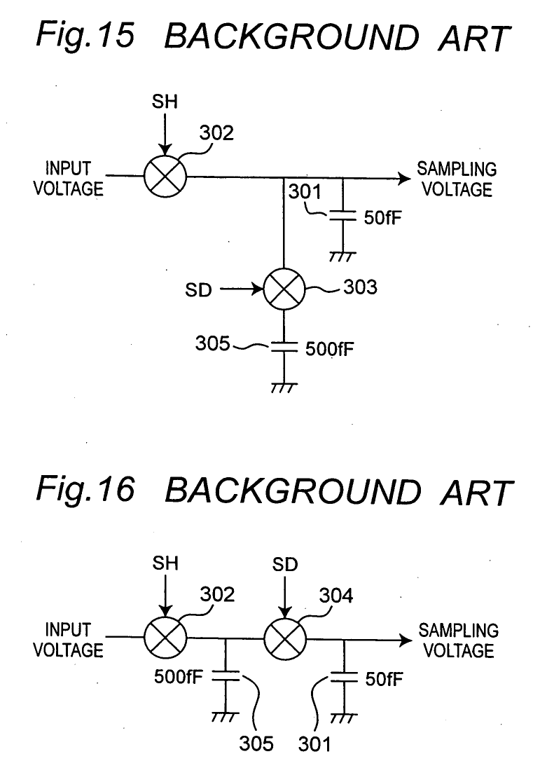

The first sample-hold circuit part 12 and the second sample-hold circuit part 13 are connected to one input of an LCD drive output amplifier 104. This is structured so that, while one sample-hold circuit is driving the LCD panel through the LCD drive output amplifier 104, the other sample-hold circuit samples and holds the driving voltage of the next stage as in the conventional structure of FIG. 11. By means of a switchover circuit (not shown), alternate switchover between the holding of the LCD drive voltage and the sampling of the voltage of the next stage is performed.

The first sample-hold circuit part 12 and the second sample-hold circuit part 13 are incorporated into an identical large scale integrated circuit (LSI) as one example of the integrated circuit (not shown). The first analog switch 1 and the second analog switch 2 are each constructed of a plurality of transistors, and the layout of the plurality of transistors that constitute the first analog switch 1 and the layout of the plurality of transistors that constitute the second analog switch 2 are same in the large scale integrated circuit. Likewise, the first analog switch 6 and the second analog switch 7 are each constructed of a plurality of transistors, and the layout of the plurality of transistors that constitute the first analog switch 6 and the layout of the plurality of transistors that constitute the second analog switch 7 are same in the large scale integrated circuit.

Moreover, in the large scale integrated circuit, the layout of components (electrode plate etc.) of the first sampling capacitor 3 and the layout of components of the second sampling capacitor 4 are identical to each other. Likewise, the layout of components (electrode plate etc.) of the first sampling capacitor 8 and the layout of components of the second sampling capacitor 9 are identical to each other.

Moreover, in the large scale integrated circuit, the layout constructions of the first sample-hold circuit part 12 and the second sample-hold circuit part 13 are also identical.

In FIG. 7, CK11A, CK21A, CK11B and CK21B indicate control signals outputted by the control section 33 in FIG. 6 to the analog switches 1, 2, 6 and 7 of the first and second sample-hold circuit parts 12 and 13, and either one of the first and second sample-hold circuit parts samples and holds the input voltage in a sequence similar to that of FIG. 2. The other of the first and second sample-hold circuit parts 12 and 13 that does not perform the sampling hold keeps a voltage holding state.

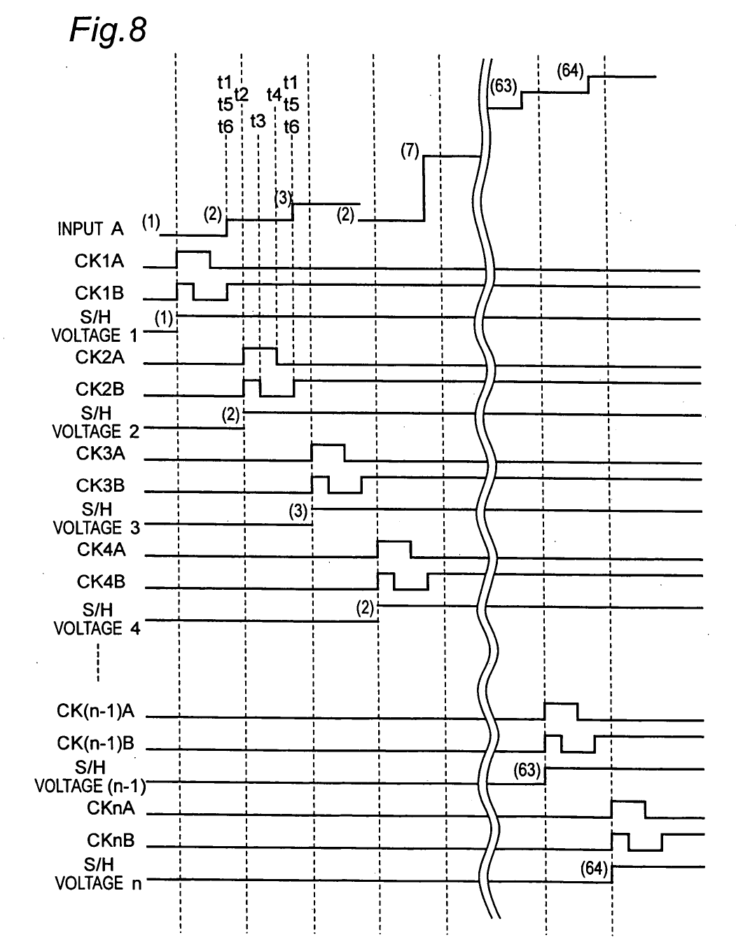

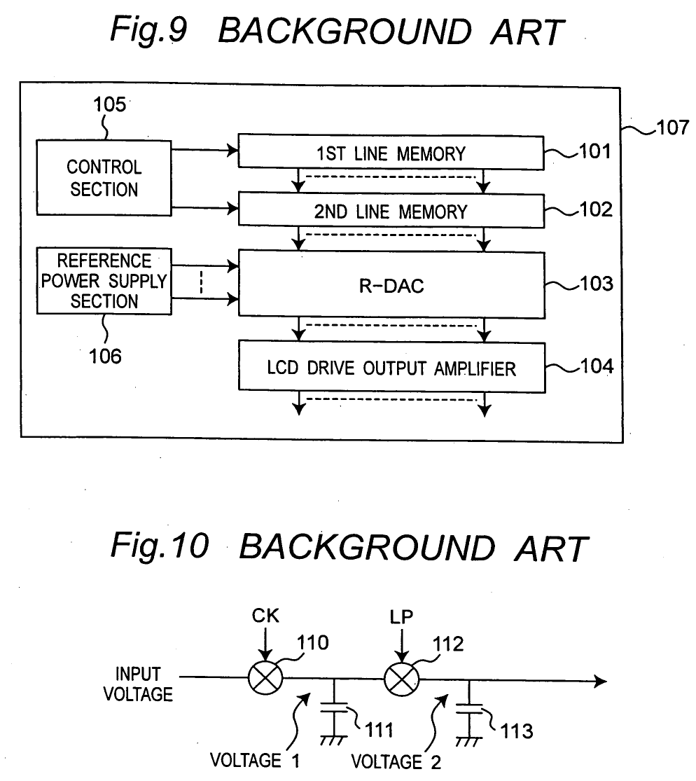

FIG. 8 is a timing chart when the sample-hold circuit of the embodiment is applied to an LCD driver. In FIG. 8, CK1A and CK1B are control signals of the analog switches of the first output, CK2A and CK2B are control signals of the analog switches of the second output, and CKnA and CKnB are control signals of the analog switches of the n-th output (n: natural number). Moreover, in FIG. 8, the parenthesized numerals such as (2) and (64) indicate gray-scale voltages. Moreover, the input A is the voltage inputted, and voltage digital data of voltages of 64-level gray scale are inputted every output.

As shown in FIG. 8, when the control signals CK1A and CKLB are outputted to the sample-hold circuit part for the first output, the control signals CK2A and CK2B are next outputted to the sample-hold circuit part for the second output. For example, in the case of 100 outputs, the control signals are subsequently successively outputted to the sample-hold circuit part for the third output, the fourth output, . . . , 99th output and the 100th output, and the control signals CK1A and CK1B are outputted to the sample-hold circuit part for the first output after the 100th output. In this case, it is a matter of course that the operation of each output is similar to the operation described with reference to FIG. 2.

In the case where the first analog switch 1 and the second analog switch 2 are constructed of identical analog switches and the first sampling capacitor 3 and the second sampling capacitor 4 are constructed of identical capacitors when the sample-hold circuit of the embodiment is part of the integrated circuit, the error of the sample-hold circuit can structurally be reduced.

For example, the first analog switch 1 is constructed of a p-channel transistor and an n-channel transistor. Further, the p-channel transistor of the first analog switch 1 and the p-channel transistor 8 (see FIG. 4) of the second analog switch 2 are constructed of identical p-channel transistors, and the n-channel transistor of the first analog switch 1 and the n-channel transistor 9 (see FIG. 4) of the second analog switch 2 are constructed of identical n-channel transistors. Moreover, the area of upper and lower electrode plates and a distance between the electrode plates of the first sampling capacitor 3 are made identical to the area of upper and lower electrode plates and a distance between the electrode plates, respectively, of the second sampling capacitor 4. With this arrangement, the parasitic capacitances of the transistors become identical, and the capacitances of the capacitors also become identical. Therefore, the error of the sample-hold circuit can be structurally reduced.

When the sample-hold circuit of the embodiment is built in a semiconductor device such as an LCD drive device or an analog signal processor, the sampling voltage error attributed to the parasitic capacitance can be corrected and reduced in the sample-hold circuit of the semiconductor device such as the LCD drive device or the analog signal processor, and it becomes unnecessary to increase the sampling capacitance in the sample-hold circuit by virtue of the correction effect. Therefore, the chip size can be reduced, and the sampling time can be reduced. Therefore, the performance of the semiconductor device can be remarkably improved.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A sample-hold circuit comprising:
a first analog switch;
a first sampling capacitor connected between an output terminal of the first analog switch and a ground;
a second analog switch whose input terminal is connected to a node between the first analog switch and the first sampling capacitor;
a second sampling capacitor connected between an output terminal of the second analog switch and the ground; and
a control section for performing first control for turning on the first and second analog switches, thereafter performing second control for turning off the second analog switch in a state in which the first analog switch is on, subsequently performing third control for turning off the first analog switch in a state in which the second analog switch is off and subsequently performing fourth control for turning on the second analog switch in a state in which the first analog switch is off.

2. The sample-hold circuit as claimed in claim 1, wherein
the control section performs the first, second, third and fourth controls during a period in which an input voltage applied to an input terminal of the first analog switch does not substantially change.

3. The sample-hold circuit as claimed in claim 2, comprising:
a digital-to-analog converter that outputs an analog voltage based on external input digital data, wherein
the input voltage is the analog voltage outputted from the digital-to-analog converter.

4. The sample-hold circuit as claimed in claim 1, wherein
the first sampling capacitor has a capacitance equal to a capacitance of the second sampling capacitor.

5. The sample-hold circuit as claimed in claim 1, wherein
the first analog switch is constituted of at least one transistor, the second analog switch is constituted of at least one transistor, and
a parasitic capacitance attributed to the at least one transistor that constitutes the first analog switch is equal to a parasitic capacitance attributed to the at least one transistor that constitutes the second analog switch.

6. The sample-hold circuit as claimed in claim 1, wherein
the first analog switch is constituted of a first p-channel transistor and a first n-channel transistor, the second analog switch is constituted of a second p-channel transistor and a second n-channel transistor, and
a parasitic capacitance of the first analog switch attributed to the first p-channel transistor and the first n-channel transistor is equal to a parasitic capacitance of the second analog switch attributed to the second p-channel transistor and the second n-channel transistor.

7. The sample-hold circuit as claimed in claim 1, wherein
the first sampling capacitor and the second sampling capacitor are built in an identical integrated circuit, and
the first sampling capacitor is roughly identical to the second sampling capacitor.

8. The sample-hold circuit as claimed in claim 7, wherein
the first analog switch and the second analog switch are built in the integrated circuit that has the first sampling capacitor and the second sampling capacitor and wherein,
the first analog switch is constituted of a plurality of transistors, the second analog switch is constituted of a plurality of transistors, and
a layout of the plurality of transistors that constitute the first analog switch is equal to a layout of the plurality of transistors that constitute the second analog switch.

9. A semiconductor device comprising the sample-hold circuit claimed in claim 1.
